(19) United States
(12) Patent Application Publication
(10) Pub. No.: US 2014/0060739 A1
(43) Pub. Date: Mar. 6, 2014

(54) RF GROUND RETURN IN PLASMA PROCESSING SYSTEMS AND METHODS THEREFOR

(71) Applicants: Rajinder Dhindsa, San Jose, CA (US); Alexei Marakhtanov, Fremont, CA (US); Michael C. Kellogg, Fremont, CA (US); Andy Desepte, Fremont, CA (US); Andrew D. Bailey, III, Fremont, CA (US)

(72) Inventors: Rajinder Dhindsa, San Jose, CA (US); Alexei Marakhtanov, Fremont, CA (US); Michael C. Kellogg, Fremont, CA (US); Andy Desepte, Fremont, CA (US); Andrew D. Bailey, III, Fremont, CA (US)

(21) Appl. No.: 13/662,331

(22) Filed: Oct. 26, 2012

Related U.S. Application Data
(60) Provisional application No. 61/696,110, filed on Aug. 31, 2012.

(51) Int. Cl. H01J 37/04

(52) U.S. Cl. CPC H01J 37/04
USPC 156/345.43

(57) ABSTRACT

Methods and apparatus for operating the plasma processing chamber of a plasma processing tool in at least two modes are disclosed. In the first mode, the substrate-bearing assembly is movable within a gap-adjustable range to adjust the gap between the electrodes to accommodate different processing requirements. In this first mode, RF ground return path continuity is maintained irrespective of the gap distance as long as the gap distance is within the gap-adjustable range. In the second mode, the substrate bearing assembly is capable of moving to further open the gap to accommodate unimpeded substrate loading/unloading.

### PRIORITY CLAIM

This application claims priority under 35 USC. 119(e) to a commonly-owned provisional patent application entitled “RF Ground Return In Plasma Processing Systems And Methods Therefor”, U.S. Application No. 61/696,110, filed on Aug. 31, 2012 by Dhindsa et al., all of which are incorporated herein by reference.

### BACKGROUND OF THE INVENTION

Plasma processing has long been employed to process substrates to form electronic integrated circuits, which may then be processed into finished electronic products. In plasma processing, a plasma processing system having one or more plasma processing chambers maybe employed to process one or more substrates into electronic integrated circuits.

Generally speaking, the plasma processing chamber is an enclosed volume within which plasma may be generated for deposition, etching, plasma cleaning, and a like. The plasma may be generated by different plasma generation technologies including, for example, inductively coupled plasma, capacitively coupled plasma, microwave, electron-cyclotron resonance (ECR) and the like.

In this patent application, the examples will be discussed with reference to a capacitively coupled plasma processing chamber. However, it should be understood that the principles and concepts discussed herein are applicable to different plasma generating technologies and different plasma processing systems.

In a typical capacitively coupled plasma processing chamber, two or more electrodes may be provided. For example, the substrate bearing structure upon which the substrate is disposed for processing may constitute one electrode, and another electrode may be disposed above the substrate bearing structure. The volume of space disposed between the two electrodes generally defines the plasma generating volume. A process source gas, which may comprise different constituent gases, maybe injected into this plasma generating volume and RF energy may be provided to one or both of the electrodes.

The RF energy generates the plasma from the process source gas, and the plasma may then be employed to process the substrate, which is disposed on a substrate bearing electrode in this example.

An inductively coupled plasma processing chamber employs an inductive antenna or coil and the inductively coupling mechanism to generate plasma in the plasma generating volume. Inductively coupled plasma processing chambers are capable of forming dense plasma and may be favored for certain applications. In recent years, plasma processing systems have also evolved to utilize both the inductively coupled mechanism and the capacitively coupled mechanism to generate plasma.

In many plasma processing chambers, the substrate bearing assembly may be movable to facilitate substrate loading and/or unloading. Once substrate loading is completed and a substrate is disposed on the substrate bearing, substrate bearing assembly may be raised to narrow the gap for plasma processing.

In other chambers, the plasma generating volume may also be varied to accommodate different recipe requirements. In a capacitively coupled plasma processing chamber, for example, the inter-electrode gap (i.e., the gap between the upper and lower electrodes) may be varied in accordance with different recipes. Irrespective of the gap size during plasma processing, it is important to maintain an RF return current conduction path in order to properly ignite and sustain a satisfactory plasma.

Embodiments of the invention pertain to methods and apparatus for enabling both capabilities in a single chamber. In one or more embodiments of the invention, a plasma processing chamber is endowed with the wide gap capability for ease of substrate loading/unloading and the narrower-but-variable gap capability for executing different recipes requiring different inter-electrode gap sizes. More importantly, embodiments of the variable gap plasma processing chamber maintain a proper RF return current conduction path irrespective of the gap size employed during plasma processing.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, for comparison purposes, a typical prior art plasma processing chamber having a movable substrate-bearing assembly.

FIG. 2 shows, in accordance with an embodiment of the present invention, an arrangement that permits a plasma processing chamber to operate in two operating states: an inter-gap adjustable operating state (the first operating state) and a substrate loading/unloading state (the second operating state).

FIG. 3 shows an example of an RF gasket 302 fitting into the groove of peripheral ground ring 208.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described hereinbelow, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various

Embodiments of the invention relates to arrangements and methods to enable a plasma processing chamber to operate in at least two operating states. In this patent application, the examples will be discussed with reference to a capacitively coupled plasma processing chamber. However, it should be understood that the principles and concepts discussed herein are applicable to different plasma generating technologies and different plasma processing systems.

In the first operating state, an RF return current path is provided from the upper ground assembly of the plasma processing chamber to the peripheral ground ring and then to the grounded shelf portion of the movable substrate-bearing assembly and eventually to the RF power supply in order to facilitate plasma processing. In this first operating state, the movable substrate bearing assembly may be moved up and down within a gap-adjustable range in order to adjust the gap between the upper electrode and the lower electrode (also referred herein as the inter-electrode gap) to accommodate recipe requirements. While the movable substrate-bearing assembly movement is within the gap-adjustable range, RF return current continuity is maintained.

In the second operating state, the movable substrate-bearing assembly is moved further away from the upper ground assembly, thereby further enlarging the inter-electrode gap than the gap that exists during gap-adjustable plasma processing state in order to facilitate substrate loading and unloading. In this second operating state, however, RF return current path continuity is not required and an RF break may exist, in one or more embodiments, between the peripheral ground ring and the upper ground assembly of the plasma processing chamber.

By providing both the ability to greatly enlarge the gap for substrate loading/unloading and the ability to adjust, while maintaining RF current continuity, the inter-electrode gap to accommodate different requirements of different recipes, greater flexibility and an improved process window are achieved.

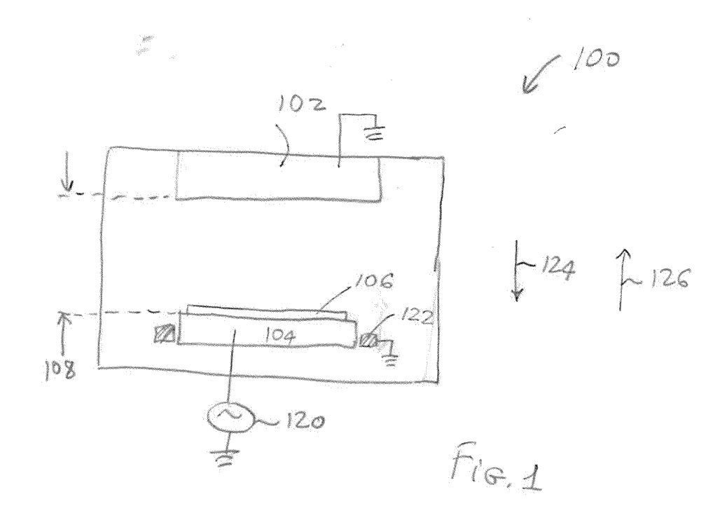

The features and advantages of embodiments of the present invention may be better understood with reference to the figures and discussions that follow. FIG. 1 shows, for comparison purposes, a typical prior art plasma processing chamber having a movable substrate-bearing assembly. The movable substrate-bearing assembly of the example of FIG. 1 may be moved downward to facilitate substrate loading/unloading or may be moved upward to close the gap to facilitate plasma processing of the substrate. During plasma processing, however, the inter-electrode gap of the plasma processing chamber of FIG. 1 is not adjustable without breaking RF return current continuity.

With reference to FIG. 1, a capacitively coupled plasma processing chamber 100 is shown (not to scale to simplify the illustration) and includes an upper ground assembly 102. A movable substrate bearing assembly 104 supports a substrate 106 during plasma processing. Generally speaking, an upper electrode is disposed in the vicinity of the lower surface of upper ground assembly 102 while a lower electrode is disposed in the vicinity of the upper surface of movable substrate bearing assembly 104.

A gap 108 exists between the lower surface of upper ground assembly 102 and the upper surface of movable substrate bearing assembly 104. The volume defined by gap 108 and surrounded by a set of confinement rings (conventional and not shown) generally defines the plasma generating region. The confinement rings serve to prevent unwanted plasma ignition outside of the plasma generating region and may also serve to control the conductance rate of exhaust gas(es) from the plasma generating region.

During plasma processing, an RF power supply 120 supplies RF energy to the lower electrode to ignite a plasma from process source gas(es) supplied into the plasma generating region. RF current flows out of the plasma in the plasma generating region and flows along the surface of upper ground assembly 102 to a peripheral ground ring 122 that surrounds movable substrate bearing assembly 104. This is conventional. The RF current is eventually returned to RF power supply 120 that provides the RF signal to movable substrate bearing assembly 104.

To facilitate the loading of substrate 106 onto the top surface of movable substrate bearing assembly 104 as well as to facilitate the unloading of substrate 106 from the top surface of movable substrate bearing assembly 104 after plasma processing is completed, gap 108 may be greatly enlarged by moving substrate bearing assembly 104 downward in the direction indicated by reference arrow 124 such that gap 108 is sufficiently large to accommodate a substrate transport robot arm.

During substrate loading, for example, the substrate transport robot arm may access the enlarged gap 108 to place substrate 106 onto the top surface of movable substrate bearing assembly 104. After substrate 106 is placed on the top surface of movable substrate bearing assembly 104, the substrate transport robot arm is removed from the chamber interior and movable substrate bearing assembly 104 is moved upward in the direction of up arrow 126 in order to narrow gap 108 again for plasma processing. The closing of gap 108 also permits peripheral ground ring 122 to establish RF contact with upper ground assembly 102, thereby establishing RF return current continuity between peripheral ground ring 122 and upper ground assembly 102. During plasma processing, the RF return current continuity permits the aforementioned RF return current to flow from the upper ground assembly 102 to peripheral ground ring 122 and eventually to RF power supply 120.

The arrangement of FIG. 1 however does not permit movable substrate bearing assembly 104 to move in the directions of arrow 124 or 126 in order to adjust gap 108 while maintaining RF return current continuity. This is because the design of the plasma processing chamber of FIG. 1 causes a break in the RF return current path to/from the upper ground assembly 102 when movable substrate bearing assembly 104 is moved downward (in the direction of arrow 124) from its fixed plasma-generating gap. Without RF return current continuity, plasma processing is impractical. Thus although the chamber design of FIG. 1 can offer the enlarged-gap capability for substrate loading/unloading purposes, the chamber design of FIG. 1 can only perform plasma processing of substrates in a fixed gap configuration.

Since modern recipes often require that the gap between the upper and lower electrode be adjustable to account for different process target requirements, embodiments of the invention facilitate both the wide opening of the inter-electrode gap to facilitate substrate loading and unloading as well as the more gradual adjustment of the narrower inter-electrode gap to accommodate different process target requirements. More importantly, RF return current continuity is maintained while the inter-electrode gap is adjusted within its gap-adjustable range.

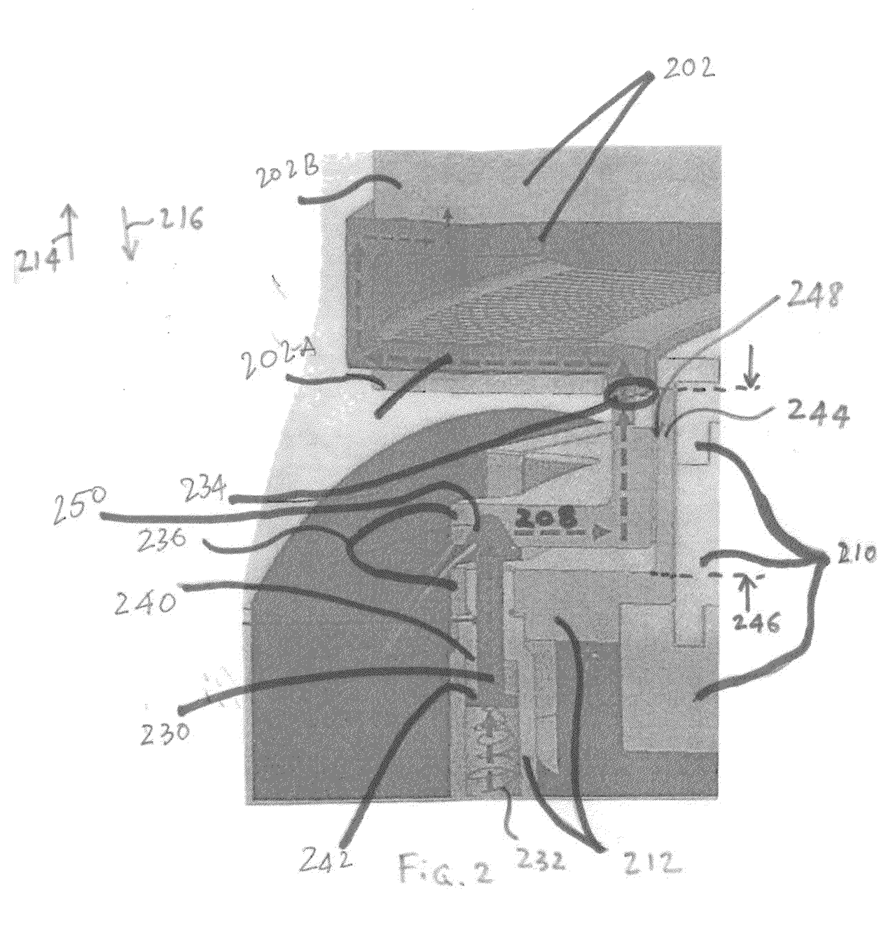

FIG. 2 shows, in accordance with an embodiment of the present invention, an arrangement that permits a plasma processing chamber to operate in two operating states: an inter-gap adjustable operating state (the first operating state) and a substrate loading/unloading state (the second operating state). The first operating state is characterized by the maintenance of an RF return current path between the upper ground assembly and the RF power supply that provides RF energy to the movable substrate bearing assembly. In this operating state, the inter-electrode gap may be set at any value within the gap-adjustable range.

The second operating state is characterized by a larger inter-electrode gap (compared to the gap adjustable operating state) such that substrate loading and unloading is facilitated. In this second operating state, there is no requirement to maintain RF return current continuity between the upper ground assembly and the RF power supply that provides RF energy to the movable substrate bearing assembly. In one or more embodiments, an RF break exists in the RF return current path between the upper ground assembly and the RF power supply that provides RF energy to the movable substrate bearing assembly.

With reference to FIG. 2, there is shown an upper ground assembly 202. In the example of FIG. 2, upper ground assembly 202 comprises a ground shroud 202A and an upper ground ring 202B, both of which are in RF contact.

A peripheral ground ring 208 is disposed around the outer periphery of movable substrate bearing assembly 210. A ground shelf portion 212 of movable substrate bearing assembly 210 is fixedly coupled to movable substrate bearing assembly 210. Thus ground shelf portion 212 also moves up and down in the directions of arrows 214 and 216 when movable substrate bearing assembly 210 moves up and down in the directions of arrow 214 and 216 to adjust the inter-electrode gap as well as to open up the inter-electrode gap to facilitate substrate loading/unloading.

In one or more embodiments, ground shelf portion 212 is electrically insulated from movable substrate bearing assembly 210 so that ground shelf portion 212 maybe grounded while movable substrate bearing assembly 210 may be powered with an RF signal.

As mentioned, peripheral ground ring 208 is disposed around the outer periphery of movable substrate bearing assembly 210 and is slidably movable in the directions of arrows 214 and 216 (i.e., in the direction parallel to the axis of movable substrate bearing assembly 210) such that peripheral ground ring 208 is slidably movable (in either a non-contacting or contacting manner) relative to movable substrate bearing assembly 210.

Peripheral ground ring 208 is supported by a plurality of pistons, of which a piston 230 is shown for illustration purposes. In the example of FIG. 2, piston 230 is spring-loaded by a spring 232 to exert an upward biasing force (in the direction of arrow 214) against peripheral ground ring 208. When movable substrate bearing assembly 210 and ground shelf portion 212 move up toward in the direction of arrow 214 to close the inter-electrode gap and the inter-electrode gap is in the variable gap range, piston 230 exerts an upward biasing force (in the direction of arrow 214) to force peripheral ground ring 208 against ground shroud 202A of upper ground assembly 202. For illustration purpose, an example confinement ring 226 is also shown. RF contact between peripheral ground ring 208 and ground shroud 202A is made in the location indicated by reference number 234 in FIG. 2.

The RF contact between peripheral ground ring 208 and ground shroud 202A allows an RF return current path to exist between upper ground assembly 202 and peripheral ground ring 208 during plasma processing. One or more flexible RF conductor(s) 236 provides an RF return current path from peripheral ground ring 208 to ground shelf portion 212. Ground shelf portion 212 is in RF ground communication with the RF power supply that provides the RF signal to movable substrate bearing assembly 210.

Thus, as movable substrate bearing assembly 210 and ground shelf portion 212 move upward in the direction of arrow 214 and the inter-electrode gap is equal to or less than the variable gap range, ground shelf portion 212 forces peripheral ground ring 208 (via the pistons) against ground shroud 202A of upper ground assembly 202. An RF return current path is established from upper ground assembly 202 to peripheral ground ring 208 to flexible RF conductor 236 to ground shelf portion 212 and eventually to the RF power supply (not shown to simplify the illustration).

Piston 230 is spring-loaded such that even if movable substrate bearing assembly 210 and ground shelf portion 212 moves downward in the direction of arrow 216 slightly while remaining within the gap-adjustable range, spring 232 still maintains an upward biasing force against piston 230 in order to bias peripheral ground ring 208 against ground shroud 202A of upper ground assembly 202 to maintain the RF return current path. Note that since RF conductor 236 is flexible (such as a flexible ground strap), RF current continuity is maintained between peripheral ground ring 208 and ground shelf portion 212 even if ground shelf portion 212 is moved relative to peripheral ground ring 208 (such as during inter-electrode gap adjustment).

When movable substrate bearing assembly 210 is moved further downward in the direction of arrow 216, surface 240 of the cylinder that houses piston 230 makes contact with shoulder 242 of piston 230 and urges shoulder 242 (and thus piston 230) downward. The movement of shoulder 242 (and with it, piston 230) downward relieves the upward bias pressure that piston 230 exerts against peripheral ground ring 208.

In this situation, the second operating state (substrate loading/unloading state) is entered during which the inter-electrode gap is greatly enlarged to facilitate substrate loading and unloading. During the substrate loading/unloading operating state, peripheral ground ring 208 moved downward by gravity since peripheral ground ring 208 is no longer urged upward against ground shroud 202A by piston 230. Thus, peripheral ground ring 208 does not impede the loading/unloading of the substrate. Further, an RF break exists in the RF return current path since peripheral ground ring 208 is no longer urged upward against ground shroud 202A by piston 230.

As can be appreciated from FIG. 2, the gap-adjustable range spans from the narrowest inter-electrode gap dimension (which is determined by chamber design) to the gap dimension whereby surface 240 makes contact with shoulder 242 of piston 230. If the inter-electrode gap dimension is larger than this gap-adjustable range, surface 240 would urge shoulder 242 downward and breaks the RF contact between peripheral ground ring 208 and ground shroud 202A as peripheral ground ring, no longer being biased upward (arrow 214 direction) by the piston, begins to fall downward (arrow 216 direction). Even though the RF return current path continuity is broken, this fact is immaterial during substrate loading/unloading since no plasma exists in the plasma generating volume during substrate loading/unloading.

A ground sleeve 244 is shown in FIG. 2. Ground sleeve 244 covers at least a portion of the outer surface of movable substrate bearing assembly 210. Ground sleeve 244 permits both peripheral ground ring 208 and ground sleeve 208 to be at about the same RF potential during plasma processing, thus vastly reducing the possibility of unwanted plasma ignition in the vertical gap 248 between ground sleeve 244 and peripheral ground ring 208. The portion covered by ground sleeve 244 has a height denoted by reference number 246 and is preferably sufficiently sized such that ground sleeve 244 always shields the outer surface of movable substrate bearing assembly 210 from direct line-of-sight with peripheral ground ring 208 during plasma processing irrespective of the inter-electrode gap dimension called for by the recipe.

In an embodiment, ground sleeve 244 may be integrated with or being formed with ground shelf portion 212. In another embodiment, ground sleeve 244 may be a separate component from ground shelf portion 212.

After substrate loading is completed, movable substrate bearing assembly 210 is then moved upward in the direction of arrow 214 to close the inter-electrode gap and to establish the RF return current path when the inter-electrode gap is equal to or less than the variable gap dimension. Generally speaking, the movement of movable substrate bearing assembly 210 may be accomplished by one or more actuators, which actuator(s) may be electrical, mechanical, hydraulic, pneumatic, or magnetic.

The upward movement of movable substrate bearing assembly 210 and attached ground shelf portion 212 moves piston 230 upward until piston 230 begins to urge peripheral ground ring 208 upward in the direction of arrow 214. At some point during the upward movement of movable substrate bearing assembly 210 and attached ground shelf portion 212, RF contact between peripheral ground ring 208 and ground shroud 202A of upper ground assembly 202 is established again at location 234 to re-create the RF return current path. The inter-electrode gap that exists when peripheral ground ring 208 first make contacts with ground shroud 202A during the upward movement of movable substrate bearing assembly 210/ground shelf portion 212 is the largest variable-gap distance (i.e., the large gap distance that can exist during plasma processing and still have RF return current continuity).

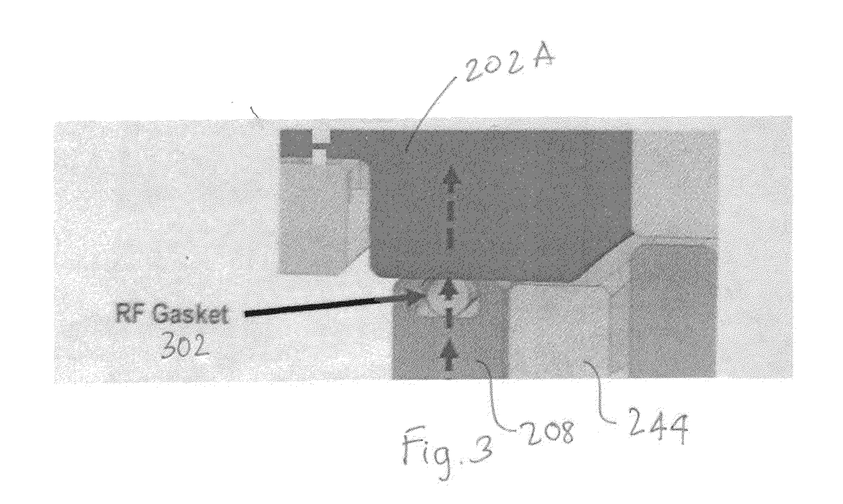

In one or more embodiments, an RF gasket may be provided between peripheral ground ring 208 and ground shroud 202A of upper ground assembly 202 to enhance RF contact performance. A spiral made from stainless steel or another suitable RF conductive material, formed in the form of a ring to fit into a groove in one of both of peripheral ground ring 208 and ground shroud 202A, represents one such suitable RF gasket. FIG. 3 shows an example of such an RF gasket 302 fitting into the groove of peripheral ground ring 208. One skilled in the art would readily appreciate from the discussion and the cut-away drawing of FIG. 2 that ground shelf portion 212, peripheral ground ring 208, ground shroud 202A, and any supplied RF gasket would generally be ring-like in form factor.

Once RF contact is made between peripheral ground ring 208 and ground shroud 202A of upper ground assembly 202, the first operating state is re-established. In this first operating state, RF return current continuity is maintained and the inter-electrode gap may be adjusted within the aforementioned gap-adjustable range without breaking the RF return current continuity between upper ground assembly 202 and the RF power supply that supplies the RF signal to the movable substrate-bearing assembly. In other words, movable substrate bearing assembly 210 may be moved up or down within the gap-adjustable range while piston 230 continues to maintain (via spring 232) the aforementioned upward biasing force to maintain RF contact between peripheral ground ring 208 and ground shroud 202A of upper ground assembly 202. The narrowest inter-electrode gap may be set by software or may be physically limited by a structure that obstructs the upward movement of substrate bearing assembly 210 and/or ground shelf portion 212 and/or a component associated therewith.

In FIG. 2, piston 230 is shown having a self-centering piston head shape 250 (which is a substantially conical shape in the example of FIG. 2). The self-centering shape of the piston head 250 allows piston 230 to be self-centered with respect to a corresponding conical cavity within peripheral ground ring 208. The spherical or elliptical shapes are other possible self-centering shapes. Thus when piston 230 moves upward to make contact with peripheral ground ring 208 (as would happen during the transition from the substrate loading/unloading operating state to the gap-adjustable plasma processing state), the pistons may be self-centered with respect to peripheral ground ring 208. Further, to ensure even lifting/lowering of peripheral ground ring 208, three pistons are employed since the use of three pistons define a plane for the movement of peripheral ground ring 208. However, more than 3 pistons may be employed with some designs if desired.

As can be appreciated from the foregoing, embodiments of the invention permit the plasma processing system to flexibly accommodate the adjustable plasma processing gap requirement of modern processing recipes while maintaining RF return current continuity as long as the inter-electrode gap remains within its gap-adjustable range. Further, embodiments of the invention facilitate unobstructed substrate loading/unloading in the second operating state as the peripheral ground ring is lowered out of the way. Embodiments of the invention accommodate both requirements, resulting in a highly flexible plasma processing chamber design capable of providing a wide variable gap process window and ease of substrate loading/unloading.

While this invention has been described in terms of several preferred embodiments, there are alterations, permutations, and equivalents, which fall within the scope of this invention. For example, although the chamber employed in the example is a capacitive chamber, embodiments of the invention work equally well with inductively coupled chambers or chambers using another type of plasma processing technology, such as Electron Cyclotron Resonance, Microwave, etc. Although various examples are provided herein, it is intended that these examples be illustrative and not limiting with respect to the invention. Further, although pistons are mentioned as the biasing mechanism, it should be understood that other forms of biasing mechanisms are also possible, including linear screws, cams, etc.

Also, the title and summary are provided herein for convenience and should not be used to construe the scope of the claims herein. Further, the abstract is written in a highly abbreviated form and is provided herein for convenience and thus should not be employed to construe or limit the overall invention, which is expressed in the claims. If the term “set” is employed herein, such term is intended to have its commonly understood mathematical meaning to cover zero, one, or more than one member. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A plasma processing chamber for plasma processing of a substrate, comprising:
an upper ground assembly;
a movable substrate-bearing assembly for supporting said substrate during said plasma processing, said movable substrate-bearing assembly having ground shelf portion, whereby a gap between an upper surface of said movable substrate-bearing assembly and a lower surface of said upper ground assembly defines a plasma generating region and whereby said movable substrate-bearing assembly is movable in a direction parallel to an axis of said movable substrate-bearing assembly to adjust said gap;
a peripheral ground ring disposed around said movable substrate bearing assembly, whereby said peripheral ground ring is slidably movable relative to said substrate-bearing assembly in a direction parallel to said axis of said movable substrate-bearing assembly;
at least one flexible RF conductor to provide RF coupling between said ground shelf portion and said peripheral ground ring;
a plurality of pistons operatively coupled to said ground shelf portion of said movable substrate bearing assembly and said peripheral ground ring, each of said plurality of pistons having a predefined stroke length to define a first operating state and a second operating state of said peripheral ground ring, said first operating state characterized by said plurality of pistons transmitting a biasing force between said ground shelf portion and said peripheral ground ring to maintain said RF contact between said peripheral ground ring and said upper ground assembly while movable substrate-bearing assembly moves in said direction parallel to said axis to adjust said gap, said second operating state characterized by an RF break between said peripheral ground ring and said upper ground assembly as said ground shelf portion of said movable substrate-bearing assembly moves away from said upper ground assembly such that said peripheral ground ring is no longer biased against said upper ground assembly by said plurality of pistons.

2. The plasma processing chamber of claim 1 wherein said plurality of pistons are spring-loaded.

3. The plasma processing chamber of claim 1 wherein said ground shelf portion is electrically insulated from at least another portion of said movable substrate-bearing assembly.

4. The plasma processing chamber of claim 3 wherein said at least another portion of said movable substrate-bearing assembly is powered with an RF signal.

5. The plasma processing chamber of claim 1 wherein said ground shelf portion includes a ground sleeve portion that covers at least a portion of an outer surface of said movable substrate bearing assembly, said sleeve portion having a sleeve height, said peripheral ground ring is disposed outside of said ground sleeve portion and movable relative to an outer surface of said ground sleeve portion.

6. The plasma processing system of claim 1 wherein a first piston of said piston includes a tapered self-centering piston head configured to be disposed in a self-centering cavity in said upper ground assembly.

7. The plasma processing system of claim 1 further comprising an RF gasket disposed between said peripheral ground ring and said upper ground assembly.

8. A plasma processing chamber for plasma processing of a substrate, comprising:
an upper ground assembly;
a movable substrate-bearing assembly for supporting said substrate during said plasma processing;
a peripheral ground ring disposed around said movable substrate bearing assembly, said peripheral ground ring being slidably movable relative to said movable substrate-bearing assembly in a direction parallel to said axis of said movable substrate-bearing assembly;
at least one flexible RF conductor to provide RF coupling between said ground shelf portion and said peripheral ground ring;
a plurality of spring-loaded pistons operatively coupled to said peripheral ground ring and said movable substrate bearing assembly to bias said peripheral ground ring against said upper ground assembly to maintain RF contact between said peripheral ground ring and said upper ground assembly while said movable substrate-bearing assembly moves in said direction parallel to said axis.

9. The plasma processing chamber of claim 8 wherein said ground shelf portion is electrically insulated from at least another portion of said movable substrate-bearing assembly.

10. The plasma processing chamber of claim 9 wherein said at least another portion of said movable substrate-bearing assembly is powered with an RF signal.

11. The plasma processing chamber of claim 8 wherein said ground shelf portion includes a ground sleeve portion that covers at least a portion of an outer surface of said movable substrate bearing assembly, said sleeve portion having a sleeve height, said peripheral ground ring is disposed outside of said ground sleeve portion and slidably moves along an outer surface of said ground sleeve portion.

12. The plasma processing system of claim 8 wherein a first piston of said piston includes a tapered self-centering piston head configured to be disposed in a self-centering cavity in said upper ground assembly.

13. The plasma processing system of claim 8 wherein said upper ground assembly includes an upper electrode and a ground peripheral shroud, said peripheral ground ring making RF contact with said ground peripheral shroud when said RF contact is formed between said peripheral ground ring and said upper ground assembly.

14. The plasma processing system of claim 8 further comprising an RF gasket disposed between said peripheral ground ring and said upper ground assembly.

15. A plasma processing chamber for plasma processing of a substrate, comprising:
an upper ground assembly;
a movable substrate-bearing assembly for supporting said substrate during said plasma processing, said movable substrate-bearing assembly having ground portion, whereby a gap between an upper surface of said movable substrate-bearing assembly and a lower surface of said upper ground assembly defines a plasma generating region and whereby said movable substrate-bearing assembly is movable in a direction parallel to an axis of said movable substrate-bearing assembly to adjust said gap;
a peripheral ground ring disposed around said movable substrate bearing assembly, whereby said peripheral ground ring is movable relative to said substrate-bearing assembly in a direction parallel to said axis of said movable substrate-bearing assembly;
at least one flexible RF conductor to provide RF coupling between said ground portion and said peripheral ground ring;
a plurality of biasing means operatively coupled to said ground portion of said movable substrate bearing assembly and said peripheral ground ring, each of said plurality of biasing means having a predefined stroke length to define a first operating state and a second operating state of said peripheral ground ring, said first operating state characterized by said plurality of biasing means transmitting a biasing force between said ground portion and said peripheral ground ring to maintain said RF contact between said peripheral ground ring and said upper ground assembly while movable substrate-bearing assembly moves in said direction parallel to said axis to adjust said gap, said second operating state characterized by an RF break between said peripheral ground ring and said upper ground assembly as said ground portion of said movable substrate-bearing assembly moves away from said upper ground assembly such that said peripheral ground ring is no longer biased against said upper ground assembly by said plurality of biasing means.

16. The plasma processing chamber of claim 15 wherein said plurality of biasing means are spring-loaded pistons.

17. The plasma processing chamber of claim 15 wherein said plasma processing chamber is a narrow gap capacitively coupled plasma processing chamber.

18. The plasma processing chamber of claim 15 wherein said ground portion is electrically insulated from at least another portion of said movable substrate-bearing assembly.

19. The plasma processing chamber of claim 18 wherein said at least another portion of said movable substrate-bearing assembly is powered with an RF signal.

20. The plasma processing chamber of claim 15 wherein said ground portion includes a ground sleeve portion that covers at least a portion of an outer surface of said movable substrate bearing assembly, said sleeve portion having a sleeve height, said peripheral ground ring is disposed outside of said ground sleeve portion and movable relative to an outer surface of said ground sleeve portion.
